(19) United States
(12) Patent Application Publication
(10) Pub. No.: US 2004/0238963 A1
(43) Pub. Date: Dec. 2, 2004

(54) Semiconductor device having structure for connecting interconnect lines

(75) Inventor: Masahiko Fujisawa, Tokyo (JP)

Correspondence Address: MCDERMOTT, WILL & EMERY, 600 13th Street, N.W., WASHINGTON, DC, 20005-3096, US

(73) Assignee: RENESAS TECHNOLOGY CORP.

(21) Appl. No.: 10/851,072

(22) Filed: May 24, 2004

(30) Foreign Application Priority Data
May 26, 2003 (JP) JP2003-147423

(51) Int. Cl. H01L 21/4763

(52) U.S. Cl. 257/758

(57) ABSTRACT

On a first Cu interconnect line formed in a first interlayer dielectric film, a second interlayer dielectric film is formed with a barrier dielectric film interposed therebetween. A second Cu interconnect line and a contact plug are formed in the second interlayer dielectric film. A Cu alloy layer is formed only in an upper portion of the first Cu interconnect line connected to the contact plug. Consequently, in an interconnection structure having the Cu interconnect lines and contact plug, the formation of voids due to stress migration is suppressed while an increase in resistance in the Cu interconnect lines and contact plug is prevented.

### BACKGROUND OF THE INVENTION

1. Field of the Invention

The present invention relates to a method of manufacturing a semiconductor device, and more particularly, to an interconnection structure mainly made of copper.

2. Description of the Background Art

With the recent trend in semiconductor devices toward finer interconnection structures, attention has been focused on copper (Cu) as a material for interconnect lines and contact plugs. However, as is already known, a phenomenon called stress migration (SM) exists, which causes a problem in the case of using copper for interconnect lines. This phenomenon is induced by stress imposed on metal interconnect lines, causing breaks in the metal interconnect lines.

Generally, microvoids are present in Cu interconnect lines formed by grain growth. When temperature rise in actual use of a device having such Cu interconnect lines causes stress on the Cu interconnect lines, microvoids in the Cu interconnect lines expand in accordance with a stress gradient to grow into large voids at a portion in which stress is concentrated. For instance, “Stress-Induced Voiding Under Vias Connected To Wide Cu Metal Leads” (E. T. Ogawa, et al., IRPS 2002 (2002 IEEE International Reliability Physics Symposium Proceeding)) reports that, in an interconnection structure made of copper, a void is likely to be formed in the upper portion of a Cu interconnect line connected to a contact plug.

To solve this SM problem, a method has been proposed by which the upper surface of Cu interconnect lines is covered with a high melting point metal or an alloy containing a high melting point metal (e.g., Japanese Patent Application Laid-Open No. 2002-118111 (columns 3-5, FIGS. 1 and 2). Since a high melting point metal or an alloy containing a high melting point metal has a higher melting point and a higher hardness than copper, atoms are less likely to move when stress is imposed thereon. Therefore, microvoids are prevented from moving in the upper portion of Cu interconnect lines covered with a high melting point metal or an alloy containing a high melting point metal. This can suppress the occurrence of voids due to SM.

Another technique is known in which metal that is diffusible in copper are buried in a via hole on a Cu interconnect line so as to serve as a contact plug, and is subjected to a thermal process, so that a metal layer is generated at the interface between the contact plug in the upper portion of the Cu interconnect line and the Cu interconnect line (Japanese Patent Application Laid-Open No. 11-204644 (1999) (columns 3-4, FIGS. 1 and 2)). Still another technique is known in which part of a barrier metal film formed on the surface of a contact plug and a Cu interconnect line located thereunder are caused to react with each other to thereby generate an alloy layer alloyed with the barrier metal in the upper portion of the Cu interconnect line (Japanese Patent No. 3329380 (columns 5-6, FIGS. 1, 3-5, 7-9)). These techniques can also suppress the occurrence of voids due to SM.

In addition, a technique is also known in which a Cu interconnect line is doped with boron, to thereby generate an alloy layer containing boron in the upper portion of the Cu interconnect line (Japanese Patent Application Laid-Open No. 2000-252278 (columns 5-6, FIGS. 1-4)). With this technique, surface diffusion is suppressed by preventing oxidization of copper, so that improvement in electromigration (EM) resistance can be expected. However, sufficient effects against the above-mentioned void formation caused by SM cannot be achieved. This is because voids due to SM are formed not only by surface diffusion of copper but also by diffusion at the interface between grains in a copper film and the like, and because a copper-boron alloy is incapable of preventing the diffusion at the grain interface.

According to Japanese Patent Application Laid-Open No. 2002-118111, part of a trench to be originally filled with copper is occupied by a high melting point metal or an alloy containing a high melting point metal. A high melting point metal or an alloy containing a high melting point metal has a resistance 10 to 100 times higher than that of copper. This disadvantageously increases wiring resistance. This disadvantageous increase in wiring resistance is significant in finer interconnect lines.

Further, according to Japanese Patent Application Laid-Open No. 11-204644, a metal having a higher resistivity than copper is used for a contact plug to be formed in a via hole, which causes an increase in wiring resistance in the whole device. Furthermore, according to Japanese Patent No. 3329380, a metallic additive for forming a Cu alloy layer is limited to a metal that functions as a barrier metal for preventing copper diffusion.

### SUMMARY OF THE INVENTION

An object of the present invention is to provide a semiconductor device capable of preventing the occurrence of voids due to stress migration as well as preventing an increase in resistance in interconnect lines and contact plugs.

The semiconductor device according to the present invention includes an interconnect line mainly made of copper, a contact plug mainly made of copper connected to an upper surface of the interconnect line, and an alloy layer formed only in an upper portion of the interconnect line connected to the contact plug, the alloy layer being obtained by adding a predetermined metallic element to copper. The predetermined metallic element contains at least one of Cr, Zr, Zn, Sc, Y, In, Sn, Mg, Co, Ag, W, Ti and Al. A metal layer made of the predetermined metallic element is not present on a sidewall of the contact plug.

Voids are unlikely to be formed by stress migration in the upper portion of the interconnect line connected to the contact plug. The alloy layer is formed only in a portion where voids are likely to be formed, which minimizes an increase in wiring resistance. The contact plug is also made of copper, and a metal layer made of the predetermined metallic element is not present on the sidewall of the contact plug 7. This can reduce the wiring resistance in the whole device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 illustrates an interconnection structure of a semiconductor device according to the present invention;

FIGS. 2 through 8 illustrate a method of manufacturing a semiconductor device according to a first preferred embodiment of the invention;

FIG. 9 illustrates a variant of the first preferred embodiment;

FIGS. 10 and 11 illustrate a method of manufacturing a semiconductor device according to a second preferred embodiment of the invention; and

FIGS. 12 to 14 illustrate a method of manufacturing a semiconductor device according to a third preferred embodiment of the invention.

### DESCRIPTION OF THE PREFERRED EMBODIMENTS

Preferred embodiments of the present invention will be described hereinbelow citing a two-layer interconnection structure for ease of description, however, the present invention is also applicable to a multilayer interconnection structure having three or more layers.

First Preferred Embodiment

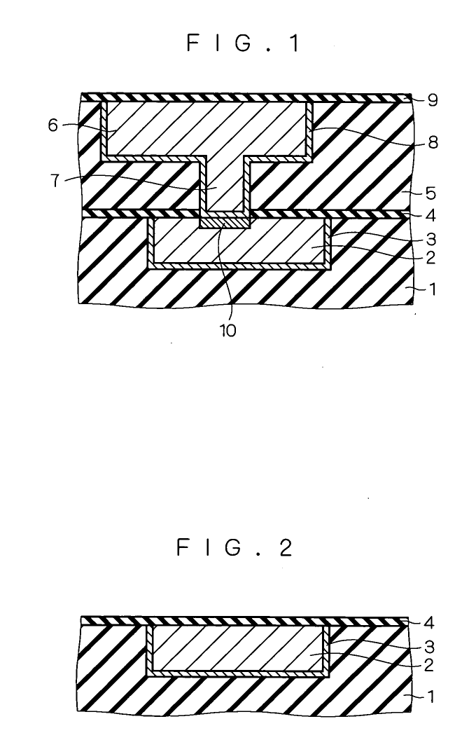

FIG. 1 illustrates an interconnection structure of a semiconductor device according to the present invention. The semiconductor device includes a first copper interconnect 2 in a first interlayer dielectric film 1 formed on a semiconductor substrate (not shown). On the side faces and the bottom of the first Cu interconnect line 2, a barrier metal 3 (made of e.g., Ta, TaN, TiN or WN) capable of preventing copper diffusion into the interlayer dielectric film 1. A second interlayer dielectric film 5 is formed on the interlayer dielectric film 1 and first Cu interconnect line 2, with a barrier dielectric film 4 capable of preventing copper diffusion into the interlayer dielectric film 5 interposed therebetween. A second Cu interconnect line 6 and a Cu contact plug 7 for connecting the second Cu interconnect line 6 and first Cu interconnect line 2 are formed in the second interlayer dielectric film 5.

A Cu alloy layer 10 is formed in an upper portion of the first Cu interconnect line 2. The Cu alloy layer 10 is formed only in the upper portion of the first Cu interconnect line 2 connected to the contact plug 7. A barrier metal 8 is formed on the surfaces of the second Cu interconnect line 6 and contact plug 7, and a barrier dielectric film 9 is formed on the second interlayer dielectric film 5 and second Cu interconnect line 6.

A void resulting from SM is likely to be formed in the upper portion of a Cu interconnect line connected to a contact plug, as above described. That is, in the structure shown in FIG. 1, a void is likely to be formed in the upper portion of the first Cu interconnect line 2 connected to the contact plug 7. In the present embodiment, the Cu alloy layer 10 is formed in that portion. Since Cu alloy generally has a higher hardness than pure copper, a microvoid is less likely to move therein, so that a void is less likely to be formed by SM. Therefore, the interconnection structure according to the present embodiment can achieve the effect of suppressing the occurrence of SM failure. Further, the alloy layer 10 is formed only in the portion where a void is likely to be formed while Cu alloy has a higher resistivity than pure copper. This minimizes an increase in resistance of the first Cu interconnect line 2. Furthermore, the contact plug 7 is also made of copper, and a metal layer having a relatively high resistance used for forming the alloy layer 10 is riot present on the sidewalls of the contact plug 7. This can reduce wiring resistance in the whole device.

Hereinbelow, a method of manufacturing the semiconductor device according to the present embodiment will be discussed. FIGS. 2 through 8 illustrate manufacturing steps. First, the first interlayer dielectric film 1 is formed on the semiconductor substrate not shown, and the first Cu interconnect line 2 and barrier metal 3 are formed in the first interlayer dielectric film 1 by a usual method (e.g., a damascene process). Then, the barrier dielectric film 4 is formed on the upper surface of the first interlayer dielectric film 1 and first Cu interconnect line 2 (FIG. 2).

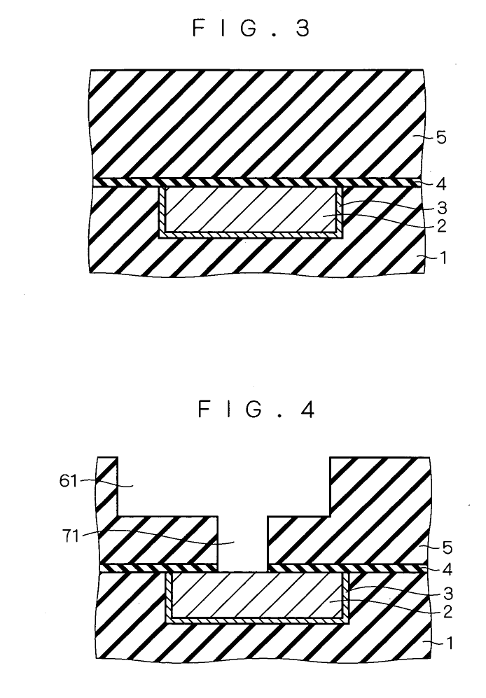

Next, the second interlayer dielectric film 5 is formed on the barrier dielectric film 4 (FIG. 3). Then, a trench 61 for forming the second Cu interconnect line 6 and a via hole 71 extending to reach the first Cu interconnect line 2 for forming the contact plug 7 are formed in the second interlayer dielectric film 5 (FIG. 4).

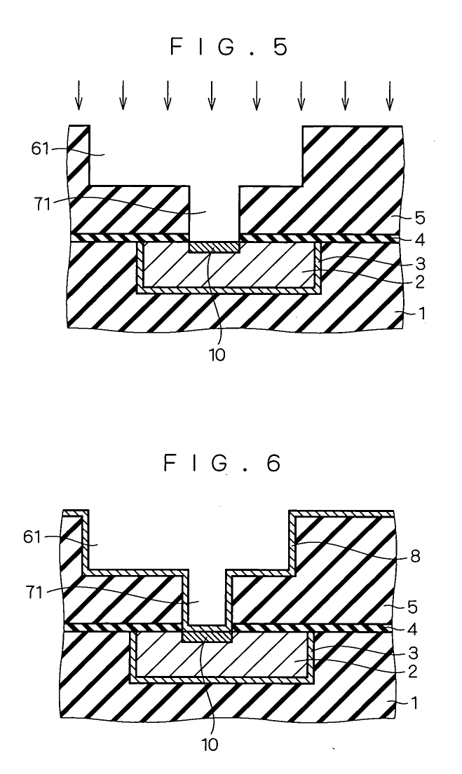

Subsequently, predetermined ions are implanted using the second interlayer dielectric film 5 with the trench 61 and via hole 71 formed therein as a mask. Thereby, the Cu alloy layer 10 is formed in a self-aligned manner only in the upper portion of the first Cu interconnect line 2 exposed in the via hole 71 (FIG. 5).

The ions implanted in the above step shall bring the alloy layer 10 to have a sufficiently high hardness, and shall contain at least one of Cr, Zr, Zn, Sc, Y, In, Sn, Mg, Co, Ag, W, Ti and Al. The use of one of these metallic elements can effectively achieve the effect of suppressing the occurrence of voids resulting from SM. When Zr is selected as the kind of ions, ion implantation is conducted at an implantation energy of 30 keV and a dose of approximately 1×10¹⁹ atom/cm². After ion implantation, a thermal process may be conducted at e.g., 400° C. for about 30 minutes in order to remove defects in the alloy layer 10.

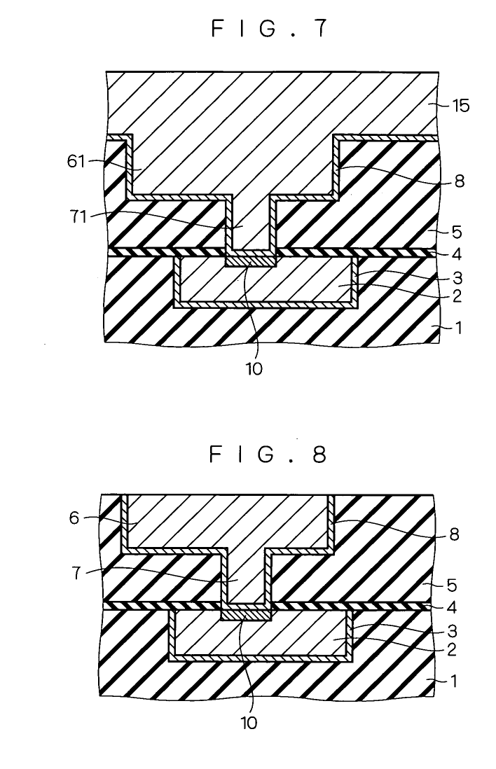

Subsequently, the barrier metal 8 is formed by, for example, a PVD (physical vapor deposition) or CVD (chemical vapor deposition) method (FIG. 6), and then, a Cu film 15 is deposited by a PVD, CVD or plating method to fill the trench 61 and via hole 71 (FIG. 7). Then, redundant portions of the barrier metal 8 and Cu film 15 on the surface of the second interlayer dielectric film 5 are removed by a CMP process or the like, so that the second Cu interconnect line 6 and contact plug 7 are formed in the trench 61 and via hole 71, respectively (FIG. 8). At last, the barrier dielectric film 9 is formed on the second interlayer dielectric film 5 and second Cu interconnect line 6. The interconnection structure shown in FIG. 1 is thereby obtained.

Through the above steps, the Cu alloy layer 10 can be formed in a self-aligned manner only in the upper portion of the first Cu interconnect line 2 connected to the contact plug 7 where voids are likely to be formed by SM. A material for forming the alloy layer 10 is not limited to those that function as a barrier metal as described in the above-mentioned Japanese Patent No. 3329380, but may be a material that enables ion implantation. In other words, the barrier metal 8 formed on the second Cu interconnect line 6 and contact plug 7 may be of a material that does not contain an element selected for ion implantation for forming the alloy layer 10. That is, a material used for forming the alloy layer 10 can be determined from a wide range of choices.

Needless to say, the first Cu interconnect line 2, second Cu interconnect line 6 and contact plug 7 may not necessarily be made of pure copper, but may be mainly made of copper.

Further, the barrier metals 3, 8 and barrier dielectric films 4, 9 are not necessarily be provided if only copper diffusion into the interlayer dielectric films is prevented by other means. These films are not required to be provided in the case where, for example, the surfaces of the first interlayer dielectric film 1 and second interlayer dielectric film 5 in contact with copper are subjected to a treatment for preventing copper diffusion, or where the first interlayer dielectric film 1 and second interlayer dielectric film 5 are made of a material into which copper does not diffuse. When the barrier metals 3, 8 and barrier dielectric films 4, 9 are not provided, the first Cu interconnect line 2, second Cu interconnect line 6 and contact plug 7 each having a low resistance can accordingly be increased in cross-sectional area, which can therefore reduce wiring resistance.

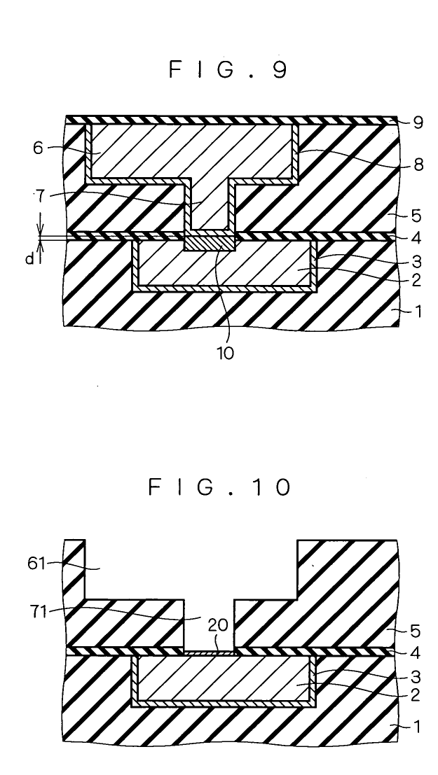

When forming the alloy layer 10 in the upper portion of the first Cu interconnect line 2, volumetric expansion may take place. This may cause the alloy layer 10 to be formed higher by the height d shown in FIG. 9 than the first interlayer dielectric film 1. Such structure shown in FIG. 9 does not deviate from the scope of the present invention, but can also achieve the effect of solving the SM problem, as described above.

The above description has been directed to a so-called dual damascene method by which the Cu film 15 is buried into the trench 61 and via hole 71 at the same time, to thereby form the second Cu interconnect line 6 and contact plug 7 at the same time, however, the present invention is not limited to this method. It is obvious that the present invention is also applicable to, for example, a so-called single damascene method by which the contact plug 7 and second Cu interconnect line 6 are sequentially formed by embedment.

Second Preferred Embodiment

In a second preferred embodiment, another method of manufacturing the semiconductor device according to the present invention shown in FIG. 1 will be described. First, similarly to the first preferred embodiment, the first interlayer dielectric film 1, first Cu interconnect line 2, barrier metal 3, barrier dielectric film 4 and second interlayer dielectric film 5 are formed on the semiconductor substrate (FIGS. 2 and 3). Next, the trench 61 for forming the second Cu interconnect line 6 and the via hole 71 extending to reach the first Cu interconnect line 2 for forming the contact plug 7 are formed in the second interlayer dielectric film 5 (FIG. 4).

Then, a predetermined metal film 20 is selectively deposited at a portion on underlying copper by a selective CVD process. That is, the metal film 20 is deposited only on the first Cu interconnect line 2 exposed in the via hole 71, and not formed on the upper surface of the second interlayer dielectric film 5, the inner surface of the trench 61 and the sidewalls of the via holes 71 (FIG. 10). The predetermined metal film 20 shall react with copper to generate a Cu alloy layer, and shall contain at least one of Cr, Zr, Zn, Sc, Y, In, Sn, Mg, Co, Ag, W, Ti and Al. For instance, a tungsten film is deposited in approximately 10 nm at a substrate temperature of 400° C., a WF₆ flow rate of 15 sccm, a H₂ flow rate of 100 sccm and a pressure of 20 mTorr.

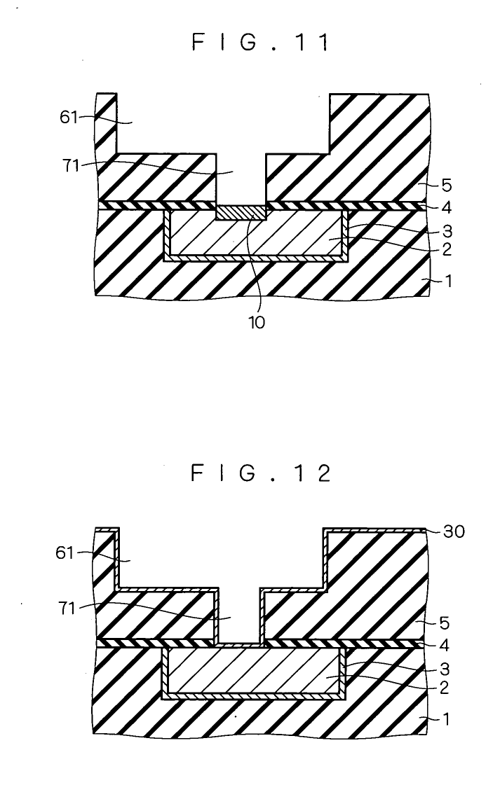

Subsequently, a thermal process is conducted (e.g., at 400° C. for about 60 minutes), to cause the first Cu interconnect line 2 and metal film 20 to react with each other, so that the Cu alloy layer 10 is generated. That is, the alloy layer 10 is formed only in the upper portion of the first Cu interconnect line 2 in the via hole 71 (FIG. 11).

Thereafter, similarly to the first preferred embodiment, the barrier metal 8 and Cu film 15 are deposited (FIGS. 6 and 7), and redundant portions of the barrier metal 8 and Cu film 15 on the upper surface of the second interlayer dielectric film 5 are removed, so that the second Cu interconnect line 6 and contact plug 7 are obtained (FIG. 8). At last, the barrier dielectric film 9 is formed. The interconnection structure shown in FIG. 1 is thereby obtained.

Through the above steps, the Cu alloy layer 10 can be formed in a self-aligned manner only in the upper portion of the first Cu interconnect line 2 connected to the contact plug 7 where voids are likely to be formed by SM. A material for forming the alloy layer 10 is not limited to those that function as a barrier metal as described in the aforementioned Japanese Patent No. 3329380, but may be one that can be deposited at a portion on underlying copper by a selective CVD process. In other words, the barrier metal 8 shall not contain an element that forms the alloy layer 10 together with copper. That is, a material used for forming the alloy layer 10 can be determined from a wide range of choices.

Further, the metal film 20, having a higher resistance than copper, is formed only on the first Cu interconnect line 2 exposed in the via hole 71, but not formed on the sidewalls of the contact plug 7 made of copper. This can reduce wiring resistance in the whole device.

Third Preferred Embodiment

In a third preferred embodiment, still another method of manufacturing the semiconductor device according to the present invention shown in FIG. 1 will be described. Similarly to the first preferred embodiment, the first interlayer dielectric film 1, first Cu interconnect line 2, barrier metal 3, barrier dielectric film 4 and second interlayer dielectric film 5 are formed on the semiconductor substrate (FIGS. 2 and 3). Next, the trench 61 for forming the second Cu interconnect line 6 and the via hole 71 extending to reach the first Cu interconnect line 2 for forming the contact plug 7 are formed in the second interlayer dielectric film 5 (FIG. 4).

In the present embodiment, a predetermined metal film 30 is deposited on the entire surface including the inner surfaces of the trench 61 and the via hole 71 by a non-selective CVD or PVD process (FIG. 12). The predetermined metal film 30 shall react with copper to generate a Cu alloy layer, and shall contain at least one of Cr, Zr, Zn, Sc, Y, In, Sn, Mg, Co, Ag, W, Ti and Al. For instance, an Al film is deposited in approximately 10 nm.

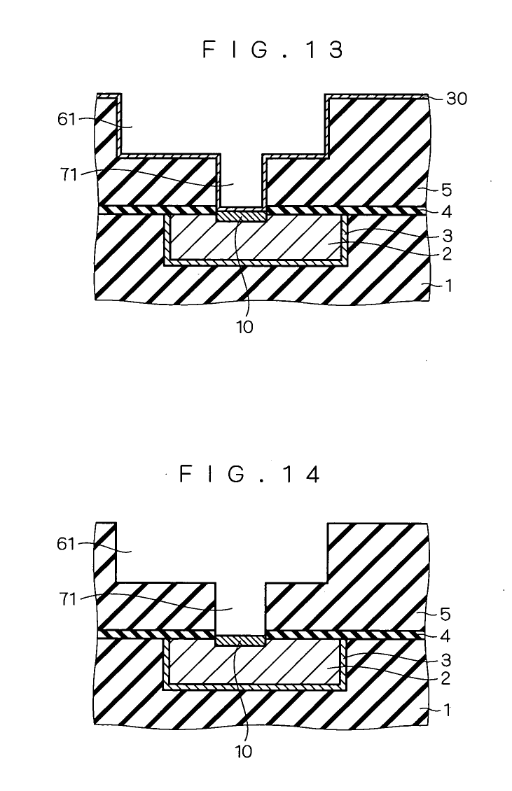

Subsequently, a thermal process is conducted (e.g., at 400° C. for about 30 minutes), to cause the first Cu interconnect line 2 and metal film 30 to react with each other, so that the Cu alloy layer 10 is generated. That is, the alloy layer 10 is formed only in the upper portion of the first Cu interconnect line 2 in the via hole 71 (FIG. 13).

Next, an unreacted portion of the metal film 30 is selectively removed using a chemical solution that dissolves the metal film 30 but does not dissolve the alloy layer 10 or second interlayer dielectric film 5 (FIG. 14). Such chemical solution varies depending on the type of metal film 30, and when an Al film or Cr film is used for the metal film 30, hydrochloric acid or sulfuric acid may be employed.

As described, it is important to remove the unreacted portion of the metal film 30 in the trench 61 and via hole 71. This is because, if the unreacted portion of the metal film 30 remains, the second Cu interconnect line 6 and contact plug 7 formed thereafter are reduced in cross-sectional area by that remaining unreacted portion, causing an increase in wiring resistance.

Thereafter, similarly to the first preferred embodiment, the barrier metal 8 and Cu film 15 are deposited (FIGS. 6 and 7), and redundant portions of the barrier metal 8 and Cu film 15 on the upper surface of the second interlayer dielectric film 5 are removed, so that the second Cu interconnect line 6 and contact plug 7 are obtained (FIG. 8). At last, the barrier dielectric film 9 is formed. The interconnection structure shown in FIG. 1 is thereby obtained.

Through the above steps, the Cu alloy layer 10 can be formed in a self-aligned manner only in the upper portion of the first Cu interconnect line 2 connected to the contact plug 7 where voids are likely to be formed by SM. A material for forming the alloy layer 10 is not limited to those that function as a barrier metal as described in the aforementioned Japanese Patent No. 3329380. However, it needs to be a material that can be deposited by a CVD process and can be removed selectively with respect to the alloy layer 10.

Further, the metal film 30 has a higher resistance than copper, however, the unreacted portion of the metal film 30 in the trench 61 and via hole 71 is removed according to the present embodiment. As a result, the metal film 30 does not remain on the sidewalls of the contact plug 7 made of copper. This can reduce wiring resistance in the whole device.

Furthermore, it is effective to implant Ar ions or N ions into the upper portion the first Cu interconnect line 2 prior to the deposition step of the metal film 30 shown in FIG. 12, using the second interlayer dielectric film 5 with the trench 61 and via hole 71 formed therein as shown in FIG. 4 as a mask, to thereby amorphize the portion of the first Cu interconnect line 2 where the alloy layer 10 is to be formed. Then, the reaction of the first Cu interconnect line 2 and metal film 30 is activated when forming the alloy layer 10 by the subsequent thermal process. The alloy layer 10 of good uniformity is thereby obtained.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
an interconnect line mainly made of copper;
a contact plug mainly made of copper connected to an upper surface of said interconnect line; and
an alloy layer formed only in an upper portion of said interconnect line connected to said contact plug, said alloy layer being obtained by adding a predetermined metallic element to copper, wherein
said predetermined metallic element contains at least one of Cr, Zr, Zn, Sc, Y, In, Sn, Mg, Co, Ag, W, Ti and Al, and
a metal layer made of said predetermined metallic element is not present on a sidewall of said contact plug.
